(19) United States
(12) Patent Application Publication
(10) Pub. No.: US 2007/0077723 A1
(43) Pub. Date: Apr. 5, 2007

(54) Method of forming shallow trench isolation in a semiconductor device

(75) Inventor: Heui-Gyun Ahn, Bucheon-city (KR)

Correspondence Address: Heui-Gyun Ahn, Kkummaeul Apt. 1009-503, Jung 2-dong, Wonmi-gu,, Bucheon-city, Kyungki-do,, KR

(73) Assignee: DongbuAnam Semiconductor Inc., Kangnam-ku (KR)

(21) Appl. No.: 11/320,725

(22) Filed: Dec. 30, 2005

(30) Foreign Application Priority Data
Sep. 30, 2005 (KR) 10-2005-0091735

(51) Int. Cl. H01L 21/76

(52) U.S. Cl. 438/424; 438/435

(57) ABSTRACT

An exemplary method of forming a shallow trench isolation layer in a semiconductor device according to an embodiment of the present invention includes depositing a silicon nitride layer as a hard mask layer on a silicon substrate, forming a first moat pattern in the silicon nitride layer by a photolithography process, patterning the silicon nitride layer by a dry etching process using the first moat pattern as an etching mask, forming a shallow trench by dry-etching the substrate that is exposed by the patterned silicon nitride layer, removing the first moat pattern after forming the shallow trench, removing the patterned silicon nitride layer, filling the shallow trench with a gap-fill insulation layer, forming a second moat pattern, removing the gap-fill insulation layer by a dry etching process using the second moat pattern as an etching mask, and removing the second moat pattern.

### CROSS-REFERENCE TO RELATED APPLICATION

THIS APPLICATION CLAIMS PRIORITY TO AND THE BENEFIT OF KOREAN PATENT APPLICATION NO. 10-2005-0091735 FILED IN THE KOREAN INTELLECTUAL PROPERTY OFFICE ON SEP. 30, 2005, THE ENTIRE CONTENTS OF WHICH ARE INCORPORATED HEREIN BY REFERENCE.

### BACKGROUND OF THE INVENTION

(a) Field of the Invention

The present invention relates to a manufacturing method of a semiconductor device. More particularly, the present invention relates to a method of forming a shallow trench isolation (STI) layer in a semiconductor device.

(b) Description of the Related Art

Recently, as manufacturing technologies for semiconductor devices have been improved, researches and developments for higher integration of semiconductor devices have been rapidly progressed. Also, with the increase of integration of semiconductor devices, studies for downsizing of the semiconductor devices based on microscopic processing technologies have been progressed. In integrating the semiconductor device, downsizing technologies for the isolation layer have become important.

An exemplary conventional isolation technology is a local oxidation of silicon (LOCOS) method wherein a thick oxide layer is selectively formed on a semiconductor substrate to form an isolation layer. However, the LOCOS method has a limit in downsizing the width of the isolation layer due to formation of oxide layers in lateral portions of the isolation layer. Therefore, the LOCOS method is inadequate for a semiconductor device where a design rule thereof is submicron, so advanced isolation technologies are required.

In a shallow trench isolation (STI) method, a shallow trench is formed in a semiconductor substrate by an etching process and filled with insulating material by a CVD method. Therefore, the device isolation region can be shrunk compared with the LOCOS method, and a planar active region can be obtained without loss of the active region.

FIG. 1A to FIG. 1G are cross-sectional views showing principal stages of forming a shallow trench isolation (STI) layer in a semiconductor device according to a conventional method. A conventional method of forming a shallow trench isolation (STI) layer will be described in detail with reference to the accompanying drawings.

As shown in FIG. 1A, on a semiconductor substrate 10 (e.g., a silicon substrate), a pad oxide (SiO₂) layer 12 that will be used as a buffer layer is formed to a thickness of 100 Å-200 Å by a thermal oxidation process. A silicon nitride (Si₃N₄) layer is deposited to a thickness of 1000 Å-3000 Å as a hard mask layer 14.

In addition, as shown in FIG. 1B, a moat pattern 16 that defines an active region and an STI region is formed on the hard mask layer 14. The moat pattern 16 is formed by coating a photoresist and performing an exposing and developing process by using an STI photomask pattern.

Subsequently, as shown in FIG. 1C, the hard mask layer 14 and the pad oxide layer 12 are sequentially patterned by a dry etching process using the moat pattern 16 as an etching mask. The dry etching process of the hard mask layer 14 is performed by an etching apparatus using a magnetically enhanced reactive ion etching (MERIE) method. CHF₃ gas and O₂ gas are used as an etching reaction gas for removing silicon nitride (Si₃N₄), and Ar gas is used as an atmosphere gas in a plasma dry etching.

Subsequently, as shown in FIG. 1D, the exposed region of the semiconductor substrate 10 by the pattern of the hard mask layer 14 and the pad oxide layer 12 is etched to a predetermined depth (e.g., 3000 Å-5000 Å). Consequently, a shallow trench 18 is formed, in which a shallow trench isolation layer will be formed. Then the moat pattern 16 is removed. After the moat pattern 16 is removed, a silicon oxide (SiO₂) layer is formed as a liner insulation layer 20 on the inner surface of the shallow trench 18 and the sidewall of the pad oxide layer 12.

As shown in FIG. 1E, a gap-fill insulation layer 22 is deposited to fill the shallow trench. For the gap-fill insulation layer, a silicon oxide layer or a tetraethyl orthosilicate (TEOS) layer may be adopted, and a high density plasma (HDP) oxide layer may be preferably adopted.

As shown in FIG. 1F, the gap-fill insulation layer 22 and the liner insulation layer 20 are polished by chemical mechanical polishing (CMP) to expose the hard mask layer 14. Reference numeral 22a denotes a gap-fill insulation layer after being planarized.

As shown in FIG. 1G, the hard mask layer 14 is removed by using a phosphoric acid solution, and the pad oxide layer 12 is partially removed. Consequently, a shallow trench isolation layer 22a according to a conventional method is formed.

In such a conventional manufacturing process for an STI layer, the shallow trench isolation layer is formed by depositing the pad oxide layer and the nitride layer, forming the moat pattern, and etching the semiconductor devices, and thereby, better characteristics of device isolation can be obtained. However, there still remain technical limitations. In order to obtain adequate device isolation characteristics, the trench should be fully filled with the oxide layer.

For example, as the gate length of a device is reduced, leakage currents may be formed in the trench isolation oxide layer. The leakage currents may be composed of diffusion currents and drift currents. The drift current flows via the shortest course between devices, and the diffusion current flows via interfaces between oxide layers. In addition, with downsizing the device, the width of the trench also becomes narrower, so processing margins may be reduced. In adopting the shallow trench, with downsizing the device, the ability of gap-filling becomes important. However, in a conventional method, the aspect ratio of the trench that is an essential factor of gap-fill characteristics may not be obtained with a sufficient processing margin.

The above information disclosed in this Background section is only for enhancement of understanding of the background of the invention and therefore it may contain information that does not form the prior art that is already known in this country to a person of ordinary skill in the art.

### SUMMARY OF THE INVENTION

The present invention has been made in an effort to provide a method of forming a shallow trench isolation (STI) layer in a semiconductor device having advantages of improving an aspect ratio of the trench.

An exemplary method of forming a shallow trench isolation (STI) layer in a semiconductor device according to an embodiment of the present invention includes: depositing a silicon nitride layer as a hard mask layer on a silicon substrate; forming a first moat pattern in the silicon nitride layer by a photolithography process; patterning the silicon nitride layer by a dry etching process using the first moat pattern as an etching mask; forming a shallow trench by dry-etching the substrate that is exposed by the patterned silicon nitride layer; removing the first moat pattern after forming the shallow trench; removing the patterned silicon nitride layer; filling the shallow trench with a gap-fill insulation layer; forming a second moat pattern; removing the gap-fill insulation layer by dry etching process using the second moat pattern as an etching mask; and removing the second moat pattern so as to form a shallow trench isolation layer.

After filling the shallow trench with a gap-fill insulation layer, the exemplary method may further include planarizing the gap-fill insulation layer by polishing.

Further, the step of forming a second moat pattern may include coating photoresist on the planarized gap-fill insulation layer and forming a photoresist pattern by exposing and developing the photoresist using a photomask.

### BRIEF DESCRIPTION OF THE DRAWINGS

FIG. 1A to FIG. 1G are cross-sectional views showing principal stages of forming shallow trench isolation (STI) in a semiconductor device according to a conventional method.

FIG. 2A to FIG. 2I are cross-sectional views showing principal stages of forming shallow trench isolation (STI) in a semiconductor device according to an exemplary embodiment of the present invention.

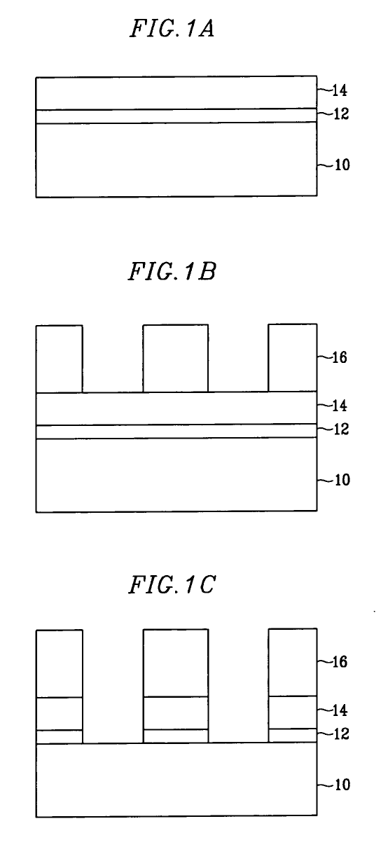

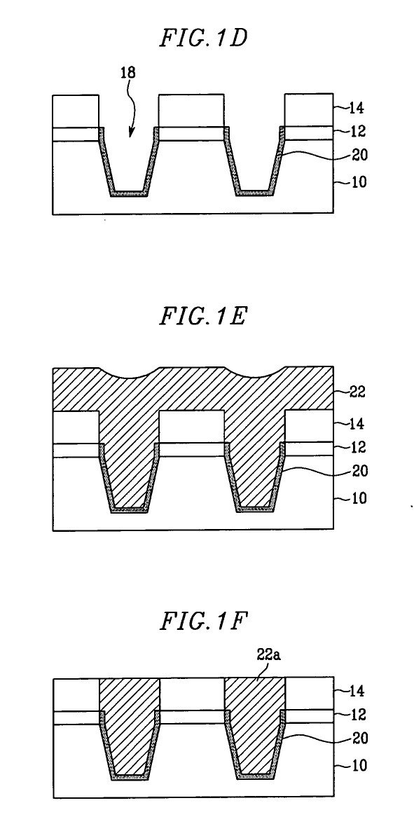

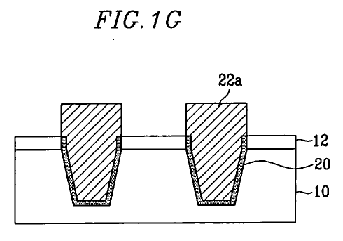

### DETAILED DESCRIPTION OF THE EMBODIMENT

An exemplary embodiment of the present invention will hereinafter be described in detail with reference to the accompanying drawings.

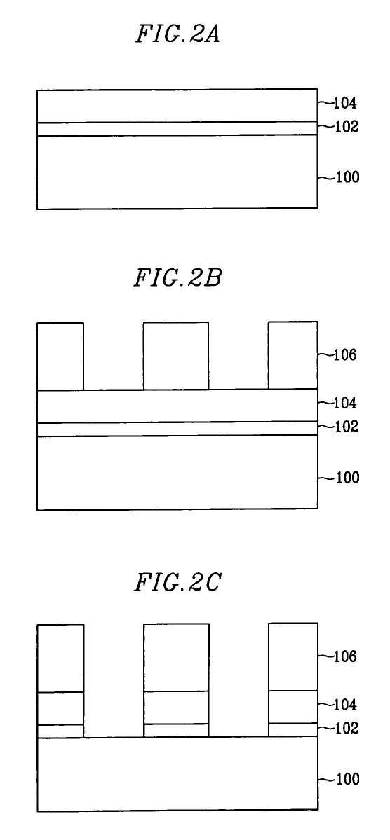

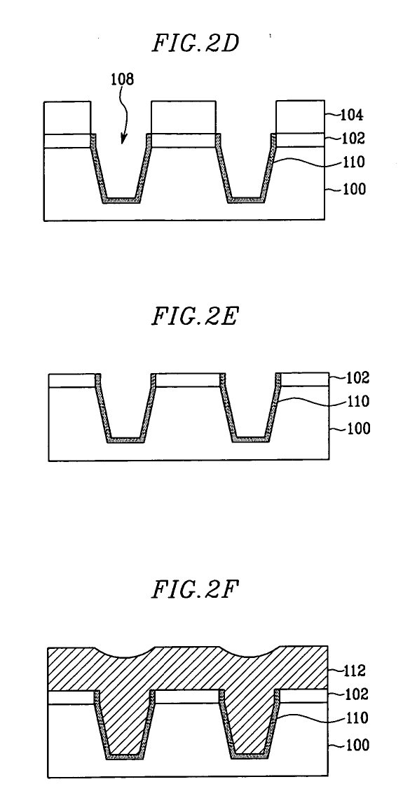

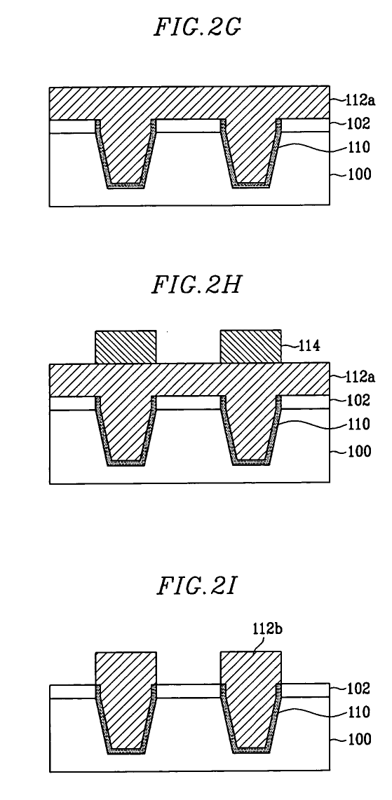

FIG. 2A to FIG. 2I are cross-sectional views showing principal stages of forming a shallow trench isolation (STI) layer in a semiconductor device according to an exemplary embodiment of the present invention. An exemplary method of forming a shallow trench isolation (STI) layer will be described with reference to those drawings.

Firstly, as shown in FIG. 2A, on a semiconductor substrate 100 (e.g., silicon substrate) a pad oxide (SiO₂) layer 102 that will be used as a buffer layer is formed to a thickness of 100 Å-200 Å by a thermal oxidation process. A silicon nitride (Si₃N₄) layer is deposited to a thickness of 1000 Å-3000 Å as a hard mask layer 104.

In addition, as shown in FIG. 2B, a first moat pattern 106 that defines an active region and an STI region is formed on the hard mask layer 104. The first moat pattern 106 is formed by coating photoresist and performing an exposing and developing process by using an STI photomask pattern.

Subsequently, as shown in FIG. 2C, the hard mask layer 104 and the pad oxide layer 102 are sequentially patterned by a dry etching process using the first moat pattern 106 as an etching mask. The dry etching process of the hard mask layer 104 is performed by an etching apparatus using a magnetically enhanced reactive ion etching (MERIE) method. CHF₃ gas and O₂ gas are used as an etching reaction gas for removing silicon nitride (Si₃N₄), and Ar gas is used as an atmosphere gas in a plasma dry etching. In such an etching process, CHF₃ gas is flowed at 40-80 sccm, O₂ gas is flowed at 0-20 sccm, and Ar gas is flowed at 6-120 sccm into the etching apparatus. In addition, a pressure of the MERIE etching apparatus is 20 mTorr-70 mTorr, and an RF power is 200 W-300 W.

Subsequently, as shown in FIG. 2D, the exposed region of the semiconductor substrate 100 by the pattern of the hard mask layer 104 and the pad oxide layer 102 is etched to a predetermined depth (e.g., 3000 Å-5000 Å). Consequently, a shallow trench 108 is formed in which a shallow trench isolation layer will be formed. Then the moat pattern 106 is removed. After the moat pattern 106 is removed, a silicon oxide (SiO₂) layer is formed as a liner insulation layer 110 on the inner surface of the shallow trench 108 and the sidewall of the pad oxide layer 102.

As shown in FIG. 2E, according to the present exemplary embodiment, the nitride layer 104 is removed. Subsequently, as shown in FIG. 2F, a gap-fill insulation layer 112 is deposited to fill the shallow trench. For the gap-fill insulation layer, a silicon oxide layer or a tetraethyl orthosilicate (TEOS) layer may be adopted, and a high density plasma (HDP) oxide layer may be preferably adopted.

By removing the nitride layer 104, an adequate processing margin of aspect ratio that is a major factor of gap-fill ability can be obtained. Considering a typical trench depth is 3000-5000 Å and a thickness of a hard mask layer (e.g., nitride layer) is generally 1000-3000 Å, the trench depth to be filled in a conventional method is 4000-8000 Å. On the contrary, the trench depth to be filled in the present exemplary embodiment can be reduced to about 3000-5000 Å. Since the trench depth to be filled can be reduced whilst the width of the trench is maintained at 1500-3000 Å, the aspect ratio can be reduced.

As shown in FIG. 2G, the gap-fill insulation layer 112 is polished by chemical mechanical polishing (CMP) so as to planarize the surface thereof. Reference numeral 112a denotes a gap-fill insulation layer after being planarized. In the planarizing of the gap-fill insulation layer, an etch-stop point can be obtained by repeating time-planarizing and monitoring.

As shown in FIG. 2H, a second moat pattern 114 for forming an isolation layer is formed on the planarized gap-fill insulation layer 112a. The second moat pattern 114 may be formed by coating a photoresist and performing an exposing and developing process by using another photomask pattern.

As shown in FIG. 2I, the gap-fill insulation layer 112a is removed by a dry etching process using the second moat pattern 114 as an etching mask, and the second moat pattern 114 is then removed. Consequently, a shallow trench isolation layer 112b according to the present exemplary embodiment is formed.

According to the exemplary embodiment of the present invention, the nitride layer is removed before filling the trench, and so the depth to be filled is reduced. Consequently, the gap-fill aspect ratio can be reduced and therefore the device can be highly integrated. In addition, because there is no need to remove the nitride layer after the planarization process, a wet-etching process using a phosphoric acid solution is not required, so the process can be simplified.

While this invention has been described in connection with what is presently considered to be a practical exemplary embodiment, it is to be understood that the invention is not limited to the disclosed embodiment, but, on the contrary, is intended to cover various modifications and equivalent arrangements included within the spirit and scope of the appended claims.

What is claimed is:

1. A method of forming a shallow trench isolation (STI) layer in a semiconductor device, comprising:
depositing a silicon nitride layer as a hard mask layer on a silicon substrate;
forming a first moat pattern in the silicon nitride layer by a photolithography process;
patterning the silicon nitride layer by a dry etching process using the first moat pattern as an etching mask;
forming a shallow trench by dry-etching the substrate that is exposed by the patterned silicon nitride layer;
removing the first moat pattern after forming the shallow trench;
removing the patterned silicon nitride layer;
filling the shallow trench with a gap-fill insulation layer;
forming a second moat pattern;
removing the gap-fill insulation layer by dry etching process using the second moat pattern as an etching mask; and
removing the second moat pattern so as to form a shallow trench isolation layer.

2. The method of claim 1, wherein a depth of the shallow trench is 3000-5000 Å.

3. The method of claim 1, wherein a width of the shallow trench is 1500-3000 Å.

4. The method of claim 1, further comprising, after filling the shallow trench with a gap-fill insulation layer, planarizing the gap-fill insulation layer by polishing.

5. The method of claim 4, wherein, in the planarizing of the gap-fill insulation layer, an etch-stop point is obtained by repeating time-planarizing and monitoring.

6. The method of claim 4, wherein the forming a second moat pattern comprises:
coating a photoresist on the planarized gap-fill insulation layer; and
forming a photoresist pattern by exposing and developing the photoresist using a photomask.

7. The method of claim 1, wherein, in the patterning the silicon nitride layer by a dry etching process, an etching apparatus using a magnetically enhanced reactive ion etching (MERIE) method is used.

8. The method of claim 7, wherein, in the patterning the silicon nitride layer by a dry etching process: an etching gas of CHF3 is flowed at 40-80 sccm, O2 is flowed at 0-20 sccm, and Ar is flowed at 6-120 sccm; a pressure of an etching chamber is maintained at 20 mTorr-70 mTorr; and an RF power is maintained at 200 W-300 W.
